(19) United States
(12) Patent Application Publication
(10) Pub. No.: US 2025/0062299 A1
(43) Pub. Date: Feb. 20, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventor: Meng-Jie LEE, Taichung City (TW)

(73) Assignee: SILICONWARE PRECISION INDUSTRIES CO., LTD., Taichung City (TW)

(21) Appl. No.: 18/403,915

(22) Filed: Jan. 4, 2024

(30) Foreign Application Priority Data
Aug. 18, 2023 (TW) 112131182

(51) Int. Cl. H01L 25/16; H01L 23/28; H01L 23/538; H01L 25/065

(52) U.S. Cl. CPC H01L 25/167; H01L 23/28; H01L 23/5383; H01L 25/0655

(57) ABSTRACT

An electronic package and a manufacturing method thereof are provided, in which an electronic module including a bridging component and an electronic component is partially arranged on a carrying structure and partially protrudes outside the carrying structure, and a photonic component is electrically connected to the protruding part of the electronic module. With this configuration, the layout area of the carrying structure can be reduced to meet the requirement of miniaturization.

### BACKGROUND

### 1. Technical Field

The present disclosure relates to a semiconductor device, and more particularly, to an electronic package with a photonic component and a manufacturing method thereof.

### 2. Description of Related Art

In response to the requirements for extensive data transmission, the development of silicon co-packaged optics (CPO) has become inevitable.

FIG. 1 is a schematic cross-sectional view of a conventional semiconductor package 1 with a photonic component. As shown in FIG. 1, a switch die 12 and an optical engine module 1a are disposed on a packaging substrate 18. The optical engine module 1a includes an encapsulation layer 15, an electrical integrated circuit (EIC) chip 11 and a plurality of conductive pillars 13 embedded in the encapsulation layer 15, a circuit structure 10 disposed on the upper side of the encapsulation layer 15, a routing structure 14 (e.g., a wiring structure) disposed on the lower side of the encapsulation layer 15, and a photonic IC 16 disposed on the circuit structure 10, such that the optical engine module 1a is disposed on the packaging substrate 18 with its routing structure 14 via a plurality of solder balls 17 (e.g., tin balls), and the optical engine module 1a is externally connected to an optical fiber 50 via the photonic IC 16 thereof. In addition, a plurality of solder balls 19 can be arranged on the lower side of the packaging substrate 18.

However, in the conventional semiconductor package 1, the switch die 12 and the optical engine module 1a are arranged adjacent to each other on the layout of the packaging substrate 18 and occupy extremely large layout area of the packaging substrate 18, so that the layout area of the packaging substrate 18 is difficult to reduce and the warpage is difficult to control. Besides, the distance between the switch die 12 and the optical engine module 1a is large, a relatively large insertion loss is prone to be occurred under high-speed operation. Furthermore, since the photonic IC 16 needs to be externally connected to the optical fiber 50, there will be interference issues with the packaging substrate 18 if the position of the photonic IC 16 is poorly designed.

Therefore, how to overcome the problems of the above-mentioned prior art has become an urgent problem to be solved at present.

### SUMMARY

In view of the aforementioned shortcomings of the prior art, the present disclosure provides an electronic package, which comprises: a carrying structure: an electronic module defined with a first connection area and a second connection area separated from each other, wherein the electronic module is connected to the carrying structure via the first connection area, and the second connection area protrudes from the carrying structure; and a photonic component connected to the second connection area of the electronic module, wherein the photonic component and the carrying structure have a gap therebetween.

The present disclosure further provides a method of manufacturing an electronic package, the method comprises: providing an electronic module defined with a first connection area and a second connection area separated from each other: electrically connecting a photonic component to the second connection area of the electronic module; and connecting the first connection area of the electronic module onto a carrying structure, wherein the second connection area protrudes from the carrying structure, and the photonic component and the carrying structure have a gap therebetween.

In the aforementioned electronic package and method, the photonic component is externally connected to an optical fiber.

In the aforementioned electronic package and method, the electronic module is electrically connected to the carrying structure via a plurality of first conductive components disposed on the first connection area, and the electronic module is electrically connected to the photonic component via a plurality of second conductive components disposed on the second connection area.

In the aforementioned electronic package and method, a dimension of each of the first conductive components located in the first connection area is greater than a dimension of each of the second conductive components located in the second connection area.

In the aforementioned electronic package and method, the gap between the carrying structure and the photonic component is at least 100 μm.

In the aforementioned electronic package and method, the carrying structure has a recess, and the photonic component is disposed in the recess of the carrying structure.

In the aforementioned electronic package and method, the electronic module comprises a plurality of the electronic components.

In the aforementioned electronic package and method, the plurality of electronic components are memory chips, electrical integrated circuit chips and switch dies.

In the aforementioned electronic package and method, the electronic module further comprises a packaging layer covering the plurality of electronic components.

In the aforementioned electronic package and method, in the electronic module, distances between side end surfaces of the plurality of electronic components and adjacent side surfaces of the packaging layer are different.

It can be seen from the above that in the electronic package and the manufacturing method thereof of the present disclosure, the plurality of electronic components are integrated into the electronic module, the electronic module is stacked with the photonic component, the electronic module is connected to the carrying structure via the first connection area and partially protrudes from the carrying structure, and the photonic component is disposed in the protruding second connection area of the electronic module. As such, the photonic component can be bonded without interfering with the carrying structure, and the layout area of the carrying structure can be reduced to meet the requirement of miniaturization.

### BRIEF DESCRIPTION OF THE DRAWINGS

FIG. 1 is a schematic cross-sectional view showing a conventional semiconductor package with a photonic component.

FIG. 2A to FIG. 2G are schematic cross-sectional views illustrating a method of manufacturing an electronic package according to the present disclosure.

FIG. 2H is a schematic cross-sectional view of the electronic package according to another embodiment of the present disclosure.

FIG. 3 is a schematic bottom view of the electronic package according to a further embodiment of the present disclosure.

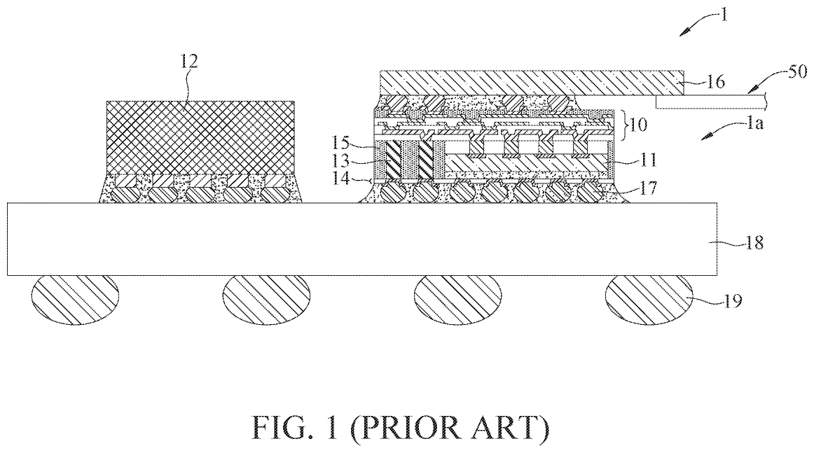

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “third,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

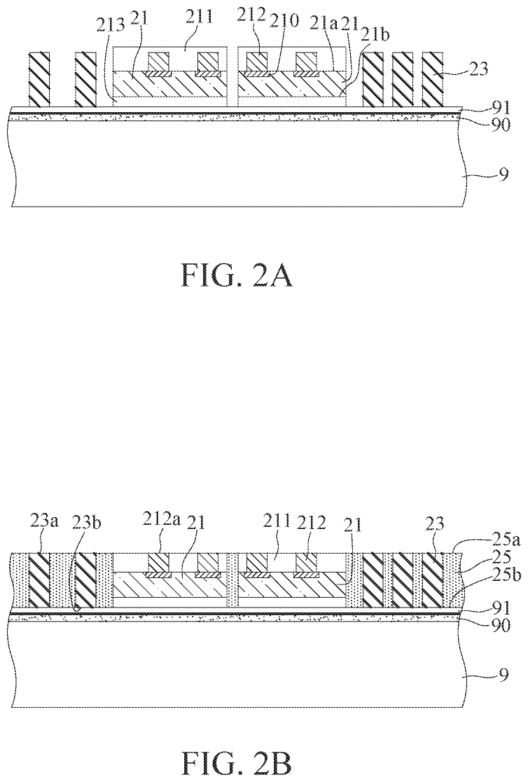

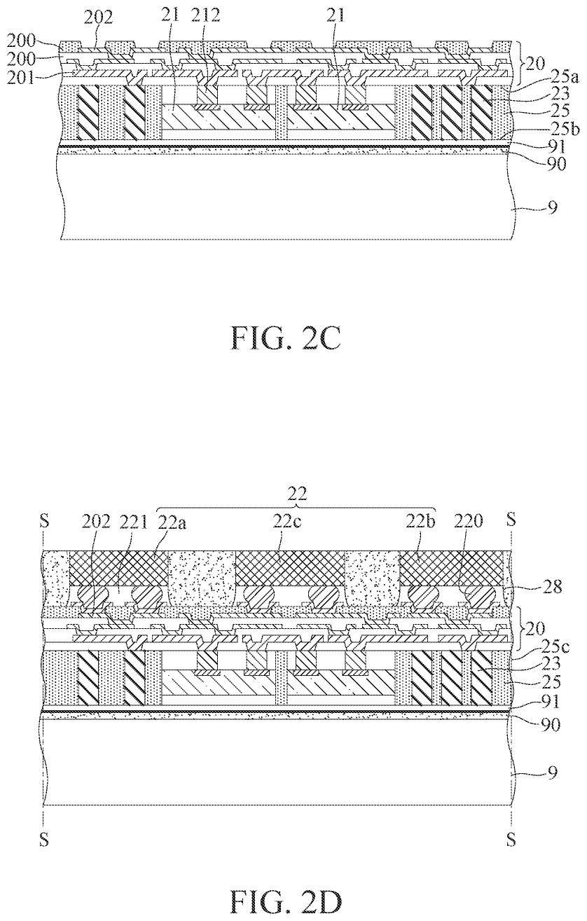

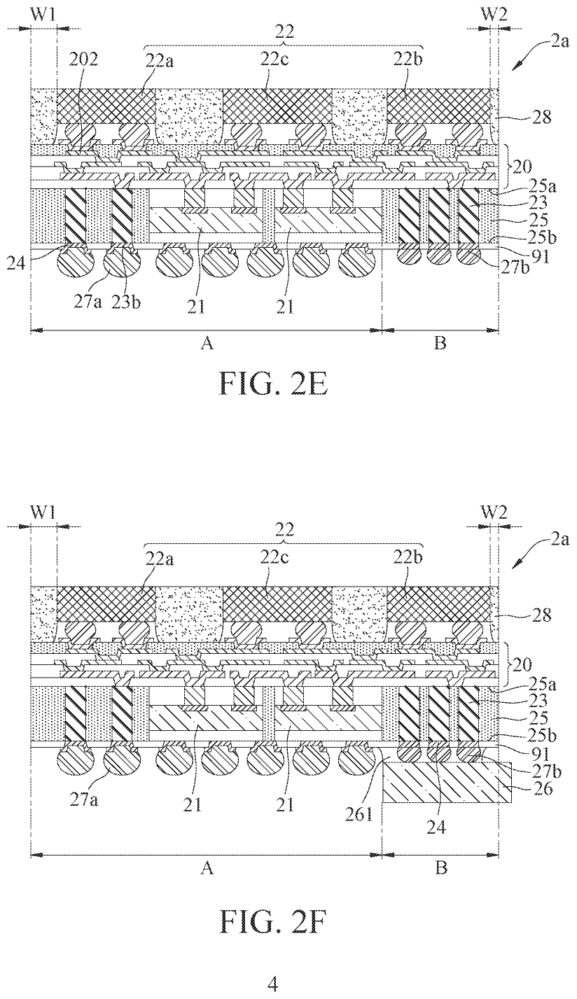

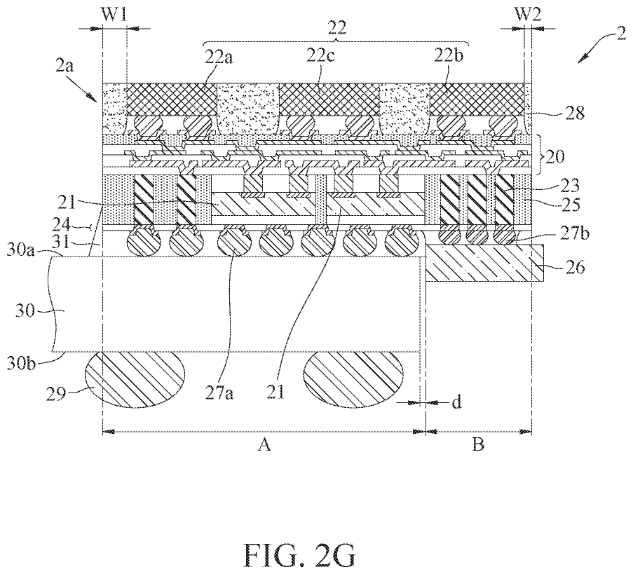

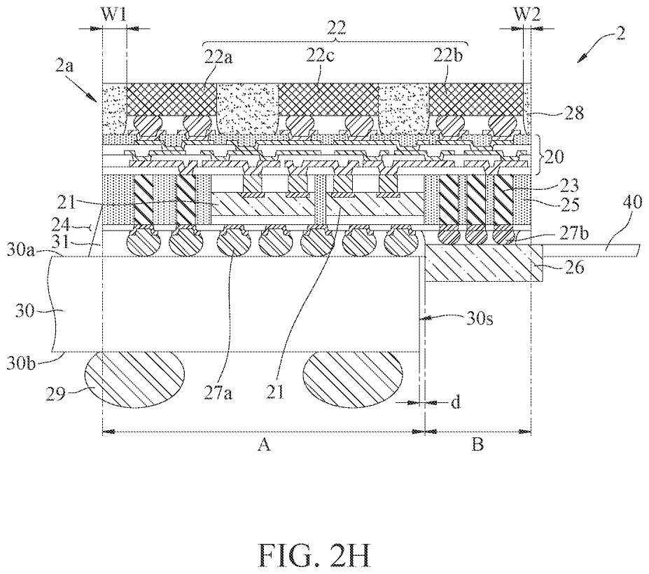

FIG. 2A to FIG. 2G are schematic cross-sectional views illustrating a method of manufacturing an electronic package 2 according to the present disclosure.

As shown in FIG. 2A, a plurality of conductive pillars 23 are formed on a carrying board 9, and at least one bridging component 21 (there are two bridging components in the embodiment) is disposed on the carrying board 9, and a plurality of conductors 212 are bonded on and electrically connected to the bridging component 21.

The carrying board 9 is, for example, a board made of semiconductor material (such as silicon or glass), on which a release layer 90 and an insulating layer 91 made of such as a dielectric material or a solder-mask material are sequentially formed by for example coating, and the plurality of conductive pillars 23 are disposed on the insulating layer 91.

The bridging component 21 is an active element, a passive element, or a combination of the active element and the passive element. The active element is such as a semiconductor chip, and the passive element is such as a resistor, a capacitor, or an inductor.

In an embodiment, the bridging component 21 is a semiconductor chip such as a driver or a trans impedance amplifier (TIA) and has an active surface 21a and an inactive surface 21b opposing the active surface 21a. The bridging component 21 is adhered onto the insulating layer 91 with its inactive surface 21b by a bonding layer 213. The active surface 21a has a plurality of electrode pads 210 and is covered with a protective film 211 made of such as a passivation material, and the plurality of conductors 212 are disposed in the protective film 211.

Moreover, the material for forming the conductive pillars 23 is a metal material such as copper or a solder material, and the conductors 212 are such as conductive circuits, solder balls in spherical shape, or metal material such as copper columns or solder bumps in column shape, or conductive parts made by a wire bonding machine in stud shape, but the present disclosure is not limited to as such.

As shown in FIG. 2B, an encapsulation layer 25 is formed on the insulating layer 91 of the carrying board 9, such that the encapsulation layer 25 covers the bridging components 21 and the conductive pillars 23, wherein the encapsulation layer 25 has a first surface 25a and a second surface 25b opposing the first surface 25a, so that the encapsulation layer 25 is bonded onto the insulating layer 91 of the carrying board 9 with its second surface 25b, and the protective film 211, end surfaces 212a of the plurality of conductors 212 and end surfaces 23a of the plurality of conductive pillars 23 are exposed from the first surface 25a of the encapsulation layer 25.

In an embodiment, the encapsulation layer 25 is made of insulating material such as polyimide (PI), dry film, encapsulating colloid of epoxy resin (epoxy), or molding compound. For instance, the encapsulation layer 25 can be formed on the insulating layer 91 by liquid compound, injection, lamination, or compression molding.

Moreover, through a leveling process, the first surface 25a of the encapsulation layer 25 is flush with the protective film 211, the end surfaces 23a of the conductive pillars 23 and the end surfaces 212a of the conductors 212, such that the end surfaces 23a of the conductive pillars 23 and the end surfaces 212a of the conductors 212 are exposed from the first surface 25a of the encapsulation layer 25. For instance, the leveling process removes part of the material of the protective film 211, part of the material of the conductive pillars 23, part of the material of the conductors 212 and part of the material of the encapsulation layer 25 by grinding.

In addition, end surfaces 23b of the conductive pillars 23 are also flush with the second surface 25b of the encapsulation layer 25.

As shown in FIG. 2C, a circuit structure 20 is formed on the first surface 25a of the encapsulation layer 25, and the circuit structure 20 is electrically connected to the plurality of conductive pillars 23 and the plurality of conductors 212.

In an embodiment, the circuit structure 20 comprises a plurality of insulation layers 200 and a plurality of redistribution layers (RDLs) 201 formed on the plurality of insulation layers 200, and the outermost insulation layer 200 can be used as a solder-mask layer, and parts of the outermost redistribution layer 201 are exposed from the solder-mask layer and served as electrical contact pads 202. Alternatively, the circuit structure 20 can also comprise a single insulation layer 200 and a single redistribution layer 201.

Moreover, the material for forming the redistribution layer 201 is copper, and the material for forming the insulation layer 200 is a dielectric material such as polybenzoxazole (PBO), polyimide (PI), prepreg (PP), or a solder-mask material such as green paint, ink, etc.

As shown in FIG. 2D, at least one electronic component 22 (three electronic components 22 are shown in the embodiment) is disposed on the circuit structure 20, and a plurality of the electronic components 22 are electrically connected to the circuit structure 20, and the plurality of electronic components 22 are covered by a packaging layer 28. Besides, the plurality of electronic components 22 can be electrically connected to each other via the circuit structure 20 and the bridging components 21.

In an embodiment, the plurality of electronic components 22 comprise a first electronic component 22a, a second electronic component 22b and a third electronic component 22c disposed between the first electronic component 22a and the second electronic component 22b. In an embodiment, the first electronic component 22a is for example a high bandwidth memory (HBM) chip, the second electronic component 22b is for example an electrical integrated circuit (EIC) chip, and the third electronic component 22c is for example a switch die. Yet the present disclosure is not limited to the above, the first electronic component 22a, the second electronic component 22b and the third electronic component 22c can also be other functional chips, and the first electronic component 22a, the second electronic component 22b and the third electronic component 22c can also be arranged in other ways.

Moreover, the electronic components 22 are electrically connected to the redistribution layer 201 of the circuit structure 20 in a flip-chip manner via a plurality of conductive bumps 220 such as solder balls, copper pillars, or others. Alternatively, the electronic components 22 can be electrically connected to the redistribution layer 201 in a wire-bonding manner via a plurality of wires (not shown). There are various ways for the electronic components 22 to be electrically connected to the redistribution layer 201, and the present disclosure is not limited to as such.

Furthermore, the packaging layer 28 is made of insulating material such as polyimide (PI), dry film, encapsulating colloid of epoxy resin (epoxy), or molding compound, and the packaging layer 28 can be formed on the circuit structure 20 by lamination or molding. It can be understood that the material for forming the packaging layer 28 can be the same or different to the material for forming the encapsulation layer 25.

In addition, the upper surface of the packaging layer 28 can be flush with the upper surfaces of the plurality of electronic components 22 by a leveling process, such that the upper surfaces of the plurality of electronic components 22 are exposed from the packaging layer 28. For instance, the leveling process removes part of the material of the packaging layer 28 and part of the material of the plurality of electronic components 22 by grinding.

Moreover, an underfill 221 can be firstly formed between the plurality of electronic components 22 and the circuit structure 20 to cover the conductive bumps 220, and then the packaging layer 28 is formed to cover the underfill 221 and the plurality of electronic components 22. Alternatively, the packaging layer 28 can be used to directly cover the conductive bumps 220.

As shown in FIG. 2E, the carrying board 9 and the release layer 90 thereon are removed and the insulating layer 91 is retained. Then, a routing structure 24 (e.g., a wiring structure) is formed on the insulating layer 91 and electrically connected to the plurality of conductive pillars 23, and a plurality of first conductive components 27a and a plurality of second conductive components 27b are bonded on the routing structure 24. Afterward, a singulation process is conducted along a cutting path S as shown in FIG. 2D to obtain a plurality of electronic modules 2a. The electronic module 2a is defined with a first connection area A and a second connection area B separated from each other, and the plurality of first conductive components 27a are bonded on the routing structure 24 of the first connection area A, and the plurality of second conductive components 27b are bonded on the routing structure 24 of the second connection area B, wherein the first conductive components 27a and the second conductive components 27b can be copper pillars or solder balls (e.g., tin balls), and the dimension of the first conductive component 27a is greater than the dimension of the second conductive component 27b. For instance, the dimension of the first conductive component 27a is 130 μm or more, and the dimension of the second conductive component 27b is 40 μm or less.

In an embodiment, the cutting path S is set in a way that in the cut electronic module 2a, the distances between the side end surfaces of the electronic components 22 on opposite sides and the adjacent side surfaces of the packaging layer 28 (or the electronic module 2a) are different. In other words, a distance W1 between the side end surface of the first electronic component 22a and the adjacent side surface of the packaging layer 28 is different from a distance W2 between the side end surface of the second electronic component 22b and the adjacent side surface of the packaging layer 28. In an embodiment, the distance W1 between the side end surface of the first electronic component 22a and the adjacent side surface of the packaging layer 28 can be at least 1400 μm, and the distance W2 between the side end surface of the second electronic component 22b and the adjacent side surface of the packaging layer 28 can be at least 700 μm.

Moreover, the insulating layer 91 can for example be formed with a plurality of openings by laser, such that the end surfaces 23b of the conductive pillars 23 are exposed from the openings for bonding with the routing structure 24.

Additionally, by providing the carrying board 9 with the insulating layer 91, the insulating layer 91 can be used to form the routing structure 24 after the carrying board 9 is removed, thereby eliminating the need to further arrange dielectric layer. Hence, the process time and the process steps can be saved to achieve the purpose of reducing the process cost.

As shown in FIG. 2F, at least one photonic component 26 such as a photonic chip is disposed on the second conductive components 27b of the second connection area B of the electronic module 2a.

In an embodiment, the second conductive components 27b can be covered by an underfill 261: alternatively, the photonic component 26 can directly contact the routing structure 24.

In addition, the photonic component 26 and the plurality of electronic components 22 can transmit signals to each other via the routing structure 24, the plurality of conductive pillars 23 and the circuit structure 20.

As shown in FIG. 2G, the electronic module 2a is connected to a carrying structure 30 via the first conductive components 27a of the first connection area A, and the first conductive components 27a are covered by an underfill 31, thereby obtaining the electronic package 2 of the present disclosure.

In an embodiment, the second connection area B of the electronic module 2a overhangs and protrudes outside a side 30s of the carrying structure 30, and there is a gap d between the photonic component 26 of the second connection area B of the electronic module 2a and the side 30s of the carrying structure 30, wherein the gap d can be at least 100 μm.

In an embodiment, the carrying structure 30 is in a form of a substrate and has a first side 30a and a second side 30b opposing the first side 30a, such that the electronic module 2a is disposed on the first side 30a of the carrying structure 30. For instance, the carrying structure 30 is a packaging substrate with a core layer and a circuit structure, or a coreless circuit structure, and the circuit structure comprises at least one insulation layer and at least one circuit layer bonded with the insulation layer, such as at least one fan-out type redistribution layer (RDL). It can be understood that the carrying structure 30 can also be other types of board, such as a lead frame, a wafer, or other types of carrying board having metal routings, but the present disclosure is not limited to as such.

As shown in FIG. 2H, subsequently, an external bus 40 such as an optical fiber cable can be externally connected on the photonic component 26 for signal transmission.

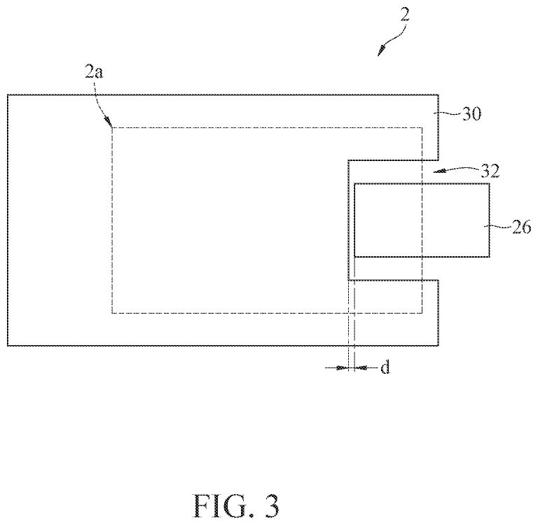

Referring to FIG. 3, FIG. 3 is a schematic bottom view of the electronic package according to a further embodiment of the present disclosure, wherein the electronic module 2a blocked by the carrying structure 30 and the photonic component 26 is represented by dotted lines. As shown in FIG. 3, the carrying structure 30 can have a recess 32 in a shape of a “c,” the photonic component 26 can be disposed in the recess 32 of the carrying structure 30, and the electronic module 2a is bridged between the carrying structure 30 and the photonic component 26. Yet the present disclosure is not limited to the above, the carrying structure 30 can also be rectangular without the recess 32, and the photonic component 26 is disposed outside of the carrying structure 30.

Additionally, a plurality of solder balls 29 can be arranged on the second side 30b of the carrying structure 30 to be connected onto an electronic device (not shown) such as a circuit board.

Therefore, in the manufacturing method of the present disclosure, the electronic module 2a is connected to the carrying structure 30 via the first connection area A and partially protrudes from the carrying structure 30, and the photonic component 26 is disposed in the protruding second connection area B of the electronic module 2a, so that the layout area of the carrying structure 30 is reduced, thereby meeting the requirement for miniaturization. In addition, since the second connection area B of the electronic module 2a overhangs and protrudes from the carrying structure 30, the connection between the photonic component 26 and the optical fiber becomes easy, thereby preventing the interference issue from occurring with the carrying structure 30.

Moreover, the quantity of the bridging component 21, the electronic component 22 and the photonic component 26 can be designed according to requirements.

The present disclosure also provides an electronic package 2, which comprises: a carrying structure 30, an electronic module 2a connected to the carrying structure 30 via a first connection area A, and a photonic component 26 electrically connected to a second connection area B of the electronic module 2a, wherein the first connection area A and the second connection area B are separated from each other.

The electronic module 2a comprises an encapsulation layer 25, at least one bridging component 21 embedded in the encapsulation layer 25, at least one conductive pillar 23 embedded in the encapsulation layer 25, a circuit structure 20 disposed on a first surface 25a of the encapsulation layer 25 and electrically connected to the bridging component 21, and at least one electronic component 22 disposed on the circuit structure 20 and electrically connected to the circuit structure 20, wherein the encapsulation layer 25 has the first surface 25a and a second surface 25b opposing the first surface 25a, so that the circuit structure 20 is disposed on the first surface 25a of the encapsulation layer 25, and the conductive pillar 23 is electrically connected to the circuit structure 20.

In an embodiment, the photonic component 26 is a photonic chip.

In an embodiment, the photonic chip is externally connected to an optical fiber.

In an embodiment, the electronic module 2a is electrically connected to the carrying structure 30 and the photonic component 26 via a first conductive component 27a and a second conductive component 27b.

In an embodiment, a dimension of the first conductive component 27a located in the first connection area A is greater than a dimension of the second conductive component 27b located in the second connection area B.

In an embodiment, a gap d between the carrying structure 30 and the photonic component 26 is at least 100 μm.

In an embodiment, the carrying structure 30 has a recess 32, and the photonic component 26 is disposed in the recess 32 of the carrying structure 30.

In an embodiment, the electronic module 2a comprises a plurality of the electronic components 22.

In an embodiment, the plurality of electronic components 22 are memory chips, electrical integrated circuit chips and switch dies.

In an embodiment, the electronic module 2a further comprises a packaging layer 28 covering the plurality of electronic components 22.

In an embodiment, in the electronic module 2a, distances W1, W2 between side end surfaces of the plurality of electronic components 22 and adjacent side surfaces of the packaging layer 28 are different.

To sum up, in the electronic package and the manufacturing method thereof of the present disclosure, the plurality of electronic components are integrated into the electronic module, the electronic module is stacked with the photonic component, the electronic module is connected to the carrying structure via the first connection area and partially protrudes from the carrying structure, and the photonic component is disposed in the protruding second connection area of the electronic module. As such, the layout area of the carrying structure can be reduced, and the requirement of miniaturization can be met.

Furthermore, since the plurality of electronic components are integrated in the electronic module, excessive insertion loss under high-speed operation due to the long distances between the switch die and other chips can be prevented, and the warpage of the carrying structure can also be avoided at the same time.

In addition, since the electronic module is configured to overhang and protrude from the carrying structure, the connection between the photonic component and the optical fiber becomes easy, thereby preventing the interference from occurring with the carrying structure.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrying structure;
an electronic module defined with a first connection area and a second connection area separated from each other, wherein the electronic module is connected to the carrying structure via the first connection area, and the second connection area protrudes from the carrying structure; and
a photonic component connected to the second connection area of the electronic module, wherein the photonic component and the carrying structure have a gap therebetween.

2. The electronic package of claim 1, wherein the photonic component is externally connected to an optical fiber.

3. The electronic package of claim 1, wherein the electronic module is electrically connected to the carrying structure via a plurality of first conductive components disposed on the first connection area, and the electronic module is electrically connected to the photonic component via a plurality of second conductive components disposed on the second connection area.

4. The electronic package of claim 3, wherein a dimension of each of the first conductive components located in the first connection area is greater than a dimension of each of the second conductive components located in the second connection area.

5. The electronic package of claim 1, wherein the gap between the carrying structure and the photonic component is at least 100 μm.

6. The electronic package of claim 1, wherein the carrying structure has a recess, and the photonic component is disposed in the recess of the carrying structure.

7. The electronic package of claim 1, wherein the electronic module comprises an encapsulation layer having a first surface and a second surface opposing the first surface, a bridging component embedded in the encapsulation layer, conductive pillars embedded in the encapsulation layer, a circuit structure disposed on the first surface of the encapsulation layer and electrically connected to the bridging component and the conductive pillars, and an electronic component disposed on and electrically connected to the circuit structure.

8. The electronic package of claim 7, wherein the electronic module comprises a plurality of the electronic components.

9. The electronic package of claim 8, wherein the plurality of electronic components are memory chips, electrical integrated circuit chips and switch dies.

10. The electronic package of claim 8, wherein the electronic module further comprises a packaging layer covering the plurality of electronic components.

11. The electronic package of claim 10, wherein in the electronic module, distances between side end surfaces of the plurality of electronic components and adjacent side surfaces of the packaging layer are different.

12. A method of manufacturing an electronic package, comprising:
providing an electronic module defined with a first connection area and a second connection area separated from each other;
electrically connecting a photonic component to the second connection area of the electronic module; and
connecting the first connection area of the electronic module onto a carrying structure, wherein the second connection area protrudes from the carrying structure, and the photonic component and the carrying structure have a gap therebetween.

13. The method of claim 12, wherein the photonic component is externally connected to an optical fiber.

14. The method of claim 12, wherein the electronic module is electrically connected to the carrying structure via a plurality of first conductive components disposed on the first connection area, and the electronic module is electrically connected to the photonic component via a plurality of second conductive components disposed on the second connection area.

15. The method of claim 14, wherein a dimension of each of the first conductive components located in the first connection area is greater than a dimension of each of the second conductive components located in the second connection area.

16. The method of claim 12, wherein the gap between the carrying structure and the photonic component is at least 100 μm.

17. The method of claim 12, wherein the carrying structure has a recess, and the photonic component is disposed in the recess of the carrying structure.

18. The method of claim 12, wherein the electronic module comprises an encapsulation layer having a first surface and a second surface opposing the first surface, a bridging component embedded in the encapsulation layer, conductive pillars embedded in the encapsulation layer, a circuit structure disposed on the first surface of the encapsulation layer and electrically connected to the bridging component and the conductive pillars, and an electronic component disposed on and electrically connected to the circuit structure.

19. The method of claim 18, wherein the electronic module comprises a plurality of the electronic components.

20. The method of claim 19, wherein the plurality of electronic components are memory chips, electrical integrated circuit chips and switch dies.

21. The method of claim 19, wherein the electronic module further comprises a packaging layer covering the plurality of electronic components.

22. The method of claim 21, wherein in the electronic module, distances between side end surfaces of the plurality of electronic components and adjacent side surfaces of the packaging layer are different.
